(19) United States
(12) Patent Application Publication
(10) Pub. No.: US 2003/0041804 A1
(43) Pub. Date: Mar. 6, 2003

(54) HDP-CVD apparatus

(75) Inventors: Kyung-Sik Shim, Sungnam (KR); Young-Suk Lee, Sungnam (KR); Soon-Bin Jung, Yongin (KR); Jeong-Beom Lee, Kwangju (KR)

Correspondence Address: OSTROLENK FABER GERB & SOFFEN, 1180 AVENUE OF THE AMERICAS, NEW YORK, NY, 100368403

(73) Assignee: Jusung Engineering Co., Ltd.

(21) Appl. No.: 10/199,360

(22) Filed: Jul. 17, 2002

(30) Foreign Application Priority Data
Aug. 30, 2001 (KR) 52824/2001

(51) Int. Cl. C23C 16/00

(52) U.S. Cl. 118/723 I; 118/715

(57) ABSTRACT

An HDP-CVD apparatus includes: a reactive chamber constructed with a lower chamber with an opened upper portion and a ceramic dome covering the upper portion of the lower chamber; a gas discharge pipe installed at the lower chamber; an RF coil installed to cover an outer wall of the ceramic dome; a gas injection pipe inserted into a wall of the ceramic dome through a marginal end portion of the ceramic dome from the outside of the reactive chamber, guided to the middle portion of the ceramic dome, and come out in the internal space of the reactive chamber at the middle portion of the ceramic dome; and a substrate support installed inside the reactive chamber in order to mount a substrate. Since the process gas is pre-heated, a reactivity is improved and a very high density plasma can be obtained. In addition, since the process gas is supplied from the upper central portion of the reactive chamber, a high density plasma can be formed at the central portion of the reactive chamber where the deposition process is substantially performed. Thus, a deposition efficiency is increased and a gap can be filled without a void.

### BACKGROUND OF THE INVENTION

1. Field of the Invention

The present invention relates to a high density plasma chemical vapor deposition (HDP-CVD) apparatus, and more particularly, to an HDP-CVD apparatus that is capable of obtaining substantially high density plasma and minimizing generation of particles inside a reactive chamber by preliminarily heating a supplied gas and activating it.

2. Description of the Background Art

As an integration of a semiconductor device is increased, a space between individual elements or metal interconnections or a width of a shallow trench isolation (STI) becomes more narrow. If an aspect ratio of the gap is increased, it is more difficult to fill the gap without a void.

Recently, a gap with a high aspect ratio is filled with an insulation material without a void by using high density plasma. That is, in a thin film deposition process using the high density plasma, since an etching simultaneously takes place by sputtering during the deposition process, the gap with a high aspect ratio can be effectively filled without a void.

Such a high density plasma can be formed by suitably applying a single frequency band RF or various frequency bands RF to a coil antenna surrounding a reactive chamber. The thusly formed plasma is called an inductively coupled plasma (ICP).

FIG. 1 is a schematic view showing a conventional HDP-CVD apparatus.

As shown in FIG. 1, a reactive chamber 10 includes a lower chamber 13 and a ceramic dome 15. An upper portion of the lower chamber 13 is opened and the ceramic dome 15 covers the opened portion of the lower chamber 13.

An RF coil 25 is wound at an outer wall of the ceramic dome 15 in order to receive an RF power and generates and maintains an HDP inside the reactive chamber 10.

A substrate support 20 is prepared inside the reactive chamber 10 in order to mount a substrate 22.

A gas injection pipe 30 is installed at a side wall of the lower chamber 13 made of a metal material, and a gas discharge pipe 40 is prepared at the bottom of the lower chamber 13.

In the conventional HDP-CVD apparatus, since a process gas is supplied from the side direction of the reactive chamber 10, the central portion of the reactive chamber 10 has a relatively low density of the process gas compared to the marginal portion. That is, the plasma density is low at the central portion. Thus, the advantage of the high density plasma process that allows a gap with a high aspect ratio to be filled without a void is not properly exhibited.

### SUMMARY OF THE INVENTION

Therefore, an object of the present invention is to provide an HDP-CVD apparatus that is capable of effectively obtaining a high density plasma and collaterally minimizing generation of particles inside a reactive chamber.

To achieve these and other advantages and in accordance with the purpose of the present invention, as embodied and broadly described herein, there is provided an HDP-CVD apparatus including: a reactive chamber constructed with a lower chamber with an opened upper portion and a ceramic dome covering the upper portion of the lower chamber; a gas discharge pipe installed at the lower chamber; an RF coil installed to cover an outer wall of the ceramic dome; a gas injection pipe inserted into a wall of the ceramic dome through a marginal end portion of the ceramic dome from the outside of the reactive chamber, guided to the middle portion of the ceramic dome, and come out in the internal space of the reactive chamber at the middle portion of the ceramic dome; and a substrate support installed inside the reactive chamber in order to mount a substrate.

In the HDP-CVD apparatus of the present invention, a hot wire may be additionally installed to cover an outer wall of the lower chamber. In such a case, it is preferred that the marginal end portion of the ceramic dome is mounted at a side wall end portion of the lower chamber, and the gas injection pipe is inserted into the side wall of the lower chamber and then inserted into the ceramic dome through the marginal end portion of the ceramic dome contacting the side wall of the lower chamber.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic view showing an HDP-CVD apparatus in accordance with a conventional art; and

FIGS. 2A and 2B are schematic views showing HDP-CVD apparatus in accordance with the present invention.

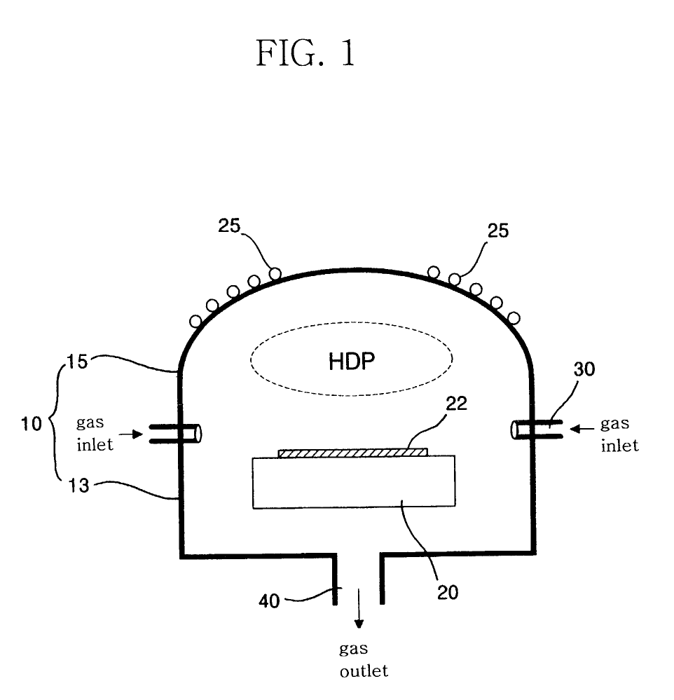

### DETAILED DESCRIPTION OF THE PREFERRED EMBODIMENTS

Reference will now be made in detail to the preferred embodiments of the present invention, examples of which are illustrated in the accompanying drawings.

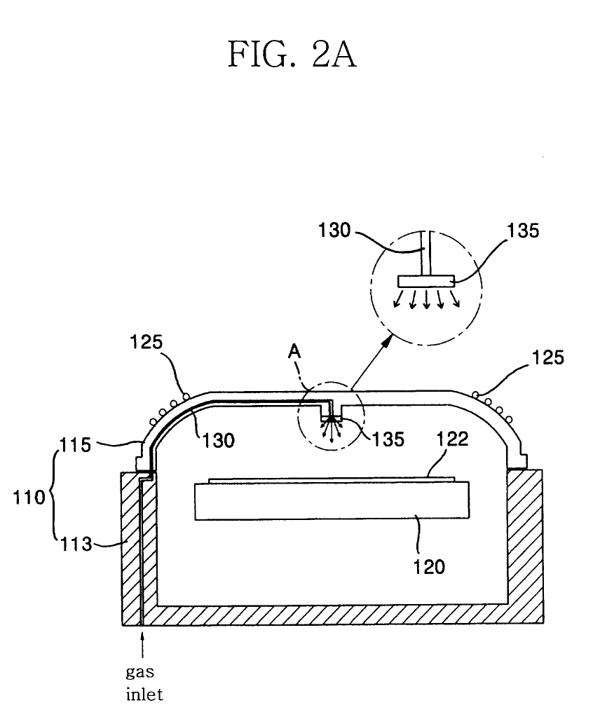

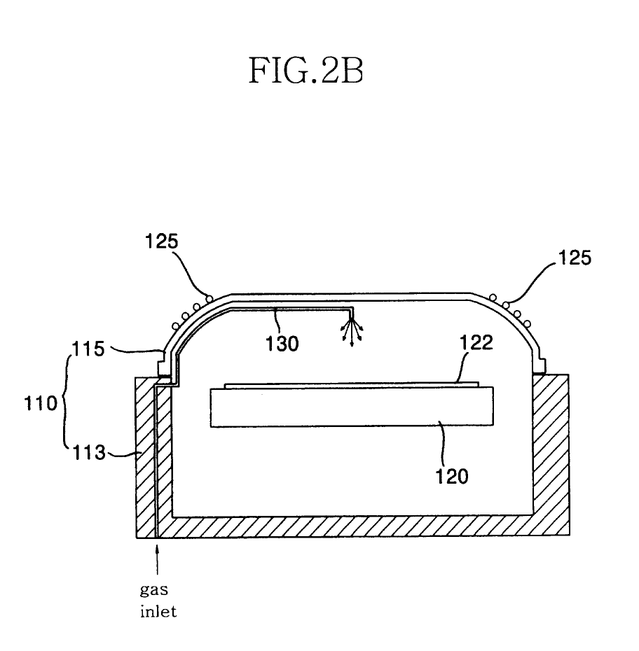

FIGS. 2A and 2B are schematic views showing HDP-CVD apparatus in accordance with the present invention.

As shown in FIG. 2A, a reactive chamber 110 is constructed with a lower chamber 113 and a ceramic dome 116, for example, a quartz dome.

An upper portion of the lower chamber 113 is opened, and the ceramic dome 116 is installed to cover the opened portion of the lower chamber 113. Specifically, the marginal end portion of the ceramic dome 115 is placed on the side wall end portion of the lower chamber 113.

An RF coil 125 is wound at an outer wall of the ceramic dome 115 in order to receive a single frequency band RF or several frequency bands RF power and generates and maintains a high density plasma inside the reactive chamber 110.

A substrate support 120 is prepared inside the reactive chamber 110 in order to mount a substrate 122. A gas discharge pipe (not shown) is prepared at the lower chamber 113 made of a metal material.

The gas injection pipe 130, a feature of the present invention, is inserted into a side wall of the lower chamber 113 from the outside of the reactive chamber 110, inserted into the ceramic dome 115 through the marginal end portion of the ceramic dome 115 contacting the side wall of the lower chamber 113, guided to the central portion of the ceramic dome 115, and then came out into the internal space of the reactive chamber 110.

In order to evenly disperse and supply a reactive gas in the internal space of the reactive chamber 110, a diffuser 135 is installed at an end portion of the gas injection pipe 130 coming out in the internal space of the reactive chamber 110.

Since the gas injection pipe 130 is inserted with a considerable length inside the ceramic dome 115, when an RF power is applied to the RF coil 125, the gas injection pipe 130 is heated to a degree by the heat generated from the RF coil 125.

Accordingly, before the process gas injected through the gas injection pipe 130 is sprayed into the internal space of the reactive chamber 110, it is pre-heated.

As the process gas is pre-heated, atoms inside the plasma are more activated by the heat energy, and thus, a reactivity is increased and a plasma density is substantially increased. Accordingly, a high density plasma with an even higher density can be obtained.

For instance, when a process gas at 20° C. is injected through the gas injection pipe 130 while applying a power of 2500 through 3500 W to the RF coil 125, a temperature of the process gas sprayed through the diffuser 135 goes up to about 350° C.

Especially, a hot wire (not shown) for degassing can be additionally installed to cover the outer side wall of the lower chamber 113 in order to remove a contaminant clinging on the inner side wall of the reactive chamber 110. When the hot wire is operated during the process, the above described preliminary heating effect can be more obtained.

In addition, since the process gas is supplied from the upper central portion of the reactive chamber 110, a high density plasma is formed at the central portion of the reactive chamber 110 where the deposition process is substantially performed.

Accordingly, the deposition efficiency is increased and the merits of the high density plasma process such as filling a gap without a void can be remarkably exhibited.

Meanwhile, FIG. 2B shows a different embodiment of the present invention, in which a portion of the gas injection pipe 130 is exposed in the internal space of the reactive chamber 110, rather than being inserted into the ceramic dome 115.

Likewise in the former embodiment of the present invention, an end portion of a gas supply pipe is formed at an upper portion of the reactive chamber, and a diffuser is attached at the end of the gas supply pipe.

With such a structure, the gas supply pipe is inserted only in the lower chamber 113, not the whole reactive chamber, and the ceramic dome 115, corresponding to an upper cover, is independently constructed.

Thus, one gas void pipe is not necessarily formed integrally with the lower chamber and the ceramic dome, and it is not necessary to close the gas supply pipe between the lower chamber and the ceramic dome like in the case that the gas supply pipe is formed at both the lower chamber and the ceramic dome.

As so far described, the HDP-CVD apparatus of the present invention has many advantages.

That is, for example, since the process gas is pre-heated, a reactivity is improved and a very high density plasma can be obtained.

In addition, since the process gas is supplied from the upper central portion of the reactive chamber, a high density plasma can be formed at the central portion of the reactive chamber where the deposition process is substantially performed. Thus, the merit of the HDP process can be maximized in that a deposition efficiency is increased and a gap can be filled without a void.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such metes and bounds are therefore intended to be embraced by the appended claims.

What is claimed is:

1. An HDP-CVD apparatus comprising:
a reactive chamber constructed with a lower chamber with an opened upper portion and a ceramic dome covering the upper portion of the lower chamber;
a gas discharge pipe installed at the lower chamber;
an RF coil installed to cover an outer wall of the ceramic dome;
a gas injection pipe inserted into a wall of the ceramic dome through a marginal end portion of the ceramic dome from the outside of the reactive chamber, guided to the middle portion of the ceramic dome, and come out in the internal space of the reactive chamber at the middle portion of the ceramic dome; and
a substrate support installed inside the reactive chamber in order to mount a substrate.

2. The apparatus of claim 1, wherein a hot wire is additionally installed to cover an outer side wall of the lower chamber.

3. The apparatus of claim 1, wherein the marginal end portion of the ceramic dome is mounted at a side wall end portion of the lower chamber, and the gas injection pipe is inserted into the side wall of the lower chamber and then inserted into the ceramic dome through the marginal end portion of the ceramic dome contacting the side wall of the lower chamber.

4. The apparatus of claim 1, wherein a diffuser is installed at the end of the gas injection pipe coming out in the internal space of the reactive chamber.
